(19) United States
(12) Patent Application Publication
(10) Pub. No.: US 2012/0227787 A1
(43) Pub. Date: Sep. 13, 2012

(54) GRAPHENE-BASED PHOTOVOLTAIC DEVICE

(76) Inventors: Tomer Drori, Tel-Aviv (IL); Elad Pollak, Modiin (IL)

(21) Appl. No.: 13/509,816

(22) PCT Filed: Oct. 18, 2010
(86) PCT No.: PCT/IL10/00849

§ 371 Date: May 15, 2012

Related U.S. Application Data
(60) Provisional application No. 61/281,261, filed on Nov. 16, 2009.
(60) Provisional application No. 61/396,154, filed on May 24, 2010.

(51) Int. Cl. H01L 31/042; H01L 31/0264; H01L 31/0224

(52) U.S. Cl. 136/244; 136/256; 136/261

(57) ABSTRACT

A photovoltaic device and a method for preparing same are described. The photovoltaic device comprises at least one pair of electrodes, wherein each member of the at least one pair of electrodes having a different working function than the other member of that pair; and one or more layers of graphene located between the two electrodes, wherein the one or more layers made of graphene have a lower working function than a working function of one member of the at least one pair of electrodes, and a higher working function than a working function of the other member of the at least one pair of electrodes, thereby allowing generation of an electric field across the photovoltaic device without applying any external voltage to the electrodes, in response to solar radiation impinging the device. Optionally, one or both electrodes have a coating of a different buffering material than the other.

### FIELD OF THE INVENTION

The present invention relates generally to photovoltaic devices and methods of using them.

### BACKGROUND OF THE INVENTION

A solar cell is a device that converts the energy of sunlight directly into electricity by utilizing photovoltaic (PV) effect. When the photons hit the solar panel they may be absorbed by semiconducting materials, such as silicon, electrons which are knocked loose from their atoms, flow through the material to produce electricity. Due to the special composition of solar cells, the electrons are only allowed to move in a single direction. This way an array of solar cells may convert solar energy into a usable amount of DC electricity. The solar radiation is composed of a spectrum of different light wavelengths extending from the ultraviolet (UV) at high energy end down to the infrared (IR). Traditionally, most PV applications utilize materials (most common is the silicon) that enable absorption of light photos only in the visible and UV ranges, while all the IR radiation cannot be converted into electrical power. Strictly speaking, when a photon emitted at the IR band and having a low energy hits the solar cell, it usually just passes straight through the silicon, whereas a photon emitted at the visible band is absorbed by the silicon and its energy is transferred to an electron in the crystal lattice. Typically this electron is present in the valence band, and is tightly bound by the covalent bonds to its neighboring atoms, hence is unable to drift apart therefrom. The energy provided to the electron the photon excites the electron into the conduction band, where it is free to move around within the semiconductor. The covalent bond, that the electron was previously a part of, now has one fewer electron—a phenomenon that is known as a hole. The presence of a missing covalent bond allows the bonded electrons of neighboring atoms to move into the “hole”, leaving another hole behind, and in this way a hole can move through the lattice.

Recently a new form of carbon, called graphene, which is a product of nanotechnology in a form of a 1 atom thick sheet, is being considered for various applications. The graphene sheet has interesting characteristics that places him as a promising candidate for use in photovoltaic devices. Nevertheless there are still inherent complications with the use of the graphene sheets and many difficulties in implementing this new material in PV applications in an efficient way. The following publications describe certain attempts that were made to implement the new form of carbon:

A. Reina, et al. present a low cost and scalable technique, via ambient pressure chemical vapor deposition (CVD) on polycrystalline Ni films, to fabricate large area (˜cm2) films of single- to few-layer graphene and to transfer the films to nonspecific substrates. A. Reina, et al. (2009) “Large Area, Few-Layer Graphene Films on Arbitrary Substrates by Chemical Vapor Deposition”. Nano Letters 9(1):30-35.

(http://www.citeulike.org/group/1282/article/3747982?citati on format=harvard#)

K. S. Kim et al. describe a technique for growing centimeter-scale films using chemical vapor deposition (CVD) on nickel films and a method to pattern and transfer the films to arbitrary substrates. The electrical conductance and optical transparency are as high as those for microscale graphene films. K. S. Kim, et al. (2009). “Large-scale pattern growth of graphene films for stretchable transparent electrodes”. Nature 457, 706-710.

(http://www.nature.com/nature/journal/v457/n7230/full/natur e07719.html)

X. Lv et al. discuss time-resolved photoconductivity measurements that are carried out on graphene films prepared by using soluble graphene oxide, and by fitting the experimental data to the Onsager model. The primary quantum yields for charge separation to generate bound electron-hole pairs and the initial ion-pair thermalization separation distance are calculated. X. Lv et al.(2009) “Photoconductivity of Bulk-Film-Based Graphene Sheets”. Small 5(14): pp. 1682-1687.

(http://www3.interscience.wiley.com/journal/122310497/abstr act?CRETRY=1&SRETRY=0)

G. Giovannetti et al. discuss devices with graphene that involve contacts with metals, and showed that when graphene is doped by adsorption on metal substrates, there is a weak bonding on Al, Ag, Cu, Au, and Pt, while it preserves its unique electronic structure, and can still shift the Fermi level with respect to the conical point by ˜0.5 eV. The graphene will become n-doped next to Al, Ag, Cu and P-doped next to Au, Pt. G. Giovannetti et al. (2008) “Doping Graphene with Metal Contacts”, Phys. Rev. Lett. 101, 026803

(http://prl.aps.org/abstract/PRL/v101/i2/e026803)

T. Mueller et al. teach of photocurrent generation on graphene, using a near-field scanning optical microscope to locally induce photocurrent in a graphene transistor with high spatial resolution. The proposed device consists of graphene placed between 2 gold electrodes while applying bias on the electrodes and measuring photocurrent, but no photovoltaic effect is achieved, as that which the present invention is interested in. T. Mueller et al. (2009) “The role of contacts in graphene transistors: A scanning photocurrent study”. Phys. Rev. B 79, 245430.

(http://arxiv.org/abs/0902.1479).

F. Xia et al. demonstrate ultra-fast transistor based photodetectors made from single and few-layer graphene. The generation and transport of photocarriers in graphene differ fundamentally from those in photodetectors made from conventional semiconductors as a result of the unique photonic and electronic properties of the graphene. This leads to a remarkably high bandwidth, zero source-drain bias and dark current operation, and good internal quantum efficiency. This publication also deals with photocurrent generation at high frequency for communication application, but does not provide any solution to how one could improve the photovoltaic effect. F. Xia et al (2009) “Ultrafast graphene photodetector”. Nature Nanotechnology 4, pp. 839 -843.

(http://www.nature.com/nnano/journal/v4/n12/abs/nnano.2009. 292.html)

E. J. H. LEE et al used scanning photocurrent microscopy to explore the impact of electrical contacts and sheet edges on charge transport through graphene devices. They found that the transition from the p-type to n-type regime induced by electrostatic gating does not occur homogeneously within the sheets. Instead, at low carrier densities one may observe the formation of p-type conducting edges surrounding a central n-type channel. E. J. H. LEE et al (2008) “Contact and edge effects in graphene devices” Nature Nanotechnology 3, 486-490.

(http://www.nature.com/nnano/journal/v3/n8/full/nnano.2008. 172.html)

US 2009071533 describes the use of transparent electrode for different devices including solar cells. The transparent electrode having high conductivity, low sheet resistance, and low surface roughness, may be prepared by employing the graphene sheet. Thus, the full potential of the graphene sheet is not utilized because this publication teaches the use of silicon as the active material and graphene for making electrodes.

US 2009146111 discloses .a reduced graphene oxide (rather than graphene sheets) doped with a dopant, and a thin layer, a transparent electrode, a display device and a solar cell including the reduced graphene oxide. The reduced graphene oxide doped with a dopant includes an organic dopant and/or an inorganic dopant.

### SUMMARY

It is an object of the present invention to provide another type of photovoltaic device than those that are known in the art.

It is another object of the present invention to provide a method for effectively generating electric power by using a photovoltaic device.

Other objects of the invention will become apparent as the description of the invention proceeds.

According to one embodiment of the present invention, a photovoltaic device is provided, the photovoltaic device, comprising:
at least one pair of electrodes wherein each member of the at least one pair of electrodes having a different working function than the other;
one or more layers made of graphene as an active material for absorbing photons received from incident solar radiation, and located between the electrodes of the at least one pair of electrodes, wherein the one or more graphene layers have a lower working function than the working function of one member of the at least one pair of electrodes.

As will be appreciated by those skilled in the art, the term “electrode” as used herein throughout the specification and claims should be understood to refer either to an electrode which is made of a core material, or to an electrode which comprises a core material and a coating of a buffering material, as long as the at least one pair of electrodes is characterized in that each of the member electrodes has a different working function than the other member of that pair, and a different working function than that of the active material (i.e. the one or more layers made of graphene). Therefore, the present invention should be understood to cover cases wherein each of the two electrodes of the at least one pair of electrodes is made of a different core material than the other, as well as cases wherein both electrodes of the at least one pair of electrodes are made of the same core material, but each has coating of a different buffering material than the other, so that the working function of one electrode (i.e. the combination of the core material and its buffering material) is different from the working function of the other electrode (i.e. the combination of ^{the} core material and its buffering material) thereby allowing generation of an electric field based on the work functions of the respective buffering materials.

According to another embodiment of the present invention, the active material comprised in the photovoltaic device has a higher working function than the working function of the other member of the at least one pair of electrodes. Due to the fact that there is a potential difference between the electrodes, an electric field may be generated across the graphene layer(s) essentially without applying any external voltage on the electrodes.

According to another embodiment of the present invention, the graphene is made of sheets and according to another embodiment of the invention, they are substantially pristine. The number of graphene sheets preferably depends on the PV device and could be varied from one to few hundreds. As an example, a PV device may comprise about 20 graphene sheets. An exact definition of the active material is provided below, however it should be noted that although throughout the specification the graphene is described as the active material, it is done only because currently this is the best mode to implement the present invention. Still, the present invention should not be considered as being limited in any way to the use of graphene only as an active material, other substances should be understood to be encompassed within the scope of the present invention.

By still another embodiment of the invention, the photovoltaic device further comprises a silicon layer located in parallel and adjacent to the graphene active material. This way, a tandem device is created wherein a silicon layer is parallel to the graphene layer, thereby enabling a better absorption of photons having various wavelengths of the solar spectrum by that photovoltaic device. Thus, it should be understood that the present invention encompasses PV devices in which graphene is used in conjunction with any other PV technology as a complementary to capture and convert preferably a different part of the solar spectrum. By the example provided above, the PV device may comprise a graphene based PV device used in a tandem setting, for example, graphene based pv device may be stacked below silicon based PV device, thereby forming a single device which comprises a combination of two separated PV devices, a graphene based PV device and a silicon based PV device.

According to still another embodiment of the invention, the graphene being the active material is comprised in a ‘sandwich type cell’, in which graphene layers are stacked in between the anode and the cathode, which are covered with an hole blocking layer and an electron blocking layer, respectively. The electric driving force in this configuration is parallel to the stacking direction.

According to yet another embodiment of the invention, the separation between the at least one pair of electrodes is smaller than about 15 microns.

In accordance with another embodiment of the present invention, the height of at least one member of the at least one pair of electrodes, is smaller than about 200 nanometers.

According to still another embodiment of the present invention, the active material is grown by using a chemical vapor deposition (CVD) technique. The one or more layers made of graphene may be grown on the same material as the one used for at least of one of the electrodes comprised in the at least one pair of electrodes.

In accordance with yet another embodiment of the present invention, at least one member of the at least one pair of electrodes comprises a buffering layer having a thickness of for example less than about 100 nanometers. A coating of such a buffering layer may, be adapted to block one type of charge carriers. For example, the at least one n-type electrode may comprise a buffering layer made of a compound comprising an alkali-metal(s) or alkali-earth element(s) and halogen(s), whereas the at least one p-type electrode may comprise a buffering layer made of a transition metal oxide characterized by having a substantially high holes' conductivity.

The photovoltaic devices described above, may be used in a form of a module and/or of a panel, for use in collecting solar radiation which comprises a plurality of such photovoltaic devices.

According to another aspect of the invention, a method for generating electric power by using a photovoltaic device is provided. The method comprising:

providing one or more layers made of graphene for use in a photovoltaic device for absorbing photons received from incident solar radiation, wherein one or more layers made of graphene have a pre-defined working function;

based on the working function of the one or more layers made of graphene, providing at least one pair of electrodes for use in the solar cell, wherein one member of the at least one pair of electrodes has a lower working function of the one or more layers made of graphene, whereas the other member of that pair has a higher working function than that of the one or more layers made of graphene;

preparing a PV device that contains the above described constituents; and

allowing generation of an electric field across the active material based on the potential difference existing between the two members of the at least one pair of electrodes.

According to another embodiment of this aspect of the present invention, at least one member of the at least one pair of electrodes comprises a buffering layer for blocking one type of charge carriers.

According to yet another embodiment of this aspect of the present invention, at least one n-type electrode of the at least one pair of electrodes comprises a compound of an alkali-metal or an alkali-earth element and halogens.

According to another embodiment, at least one p-type electrode of the at least one pair of electrodes comprises a transition metal oxide characterized by having a substantially high holes' conductivity.

### BRIEF DESCRIPTION OF THE DRAWINGS

A better understanding of the present invention may be obtained when the following non-limiting detailed description is considered in conjunction with the accompanying figures.

FIG. 1—presents an energy diagram that demonstrates the energy level of the working function of two example electrodes and an example active material according to one embodiment of the present invention;

FIG. 2—provides schematic views of a photovoltaic device according to an embodiment of present invention.

FIG. 2A—is a top view of a photovoltaic device according to an embodiment of the present invention;

FIG. 2B—is a side view of a photovoltaic device according to an embodiment of the present invention;

FIG. 3—illustrates a schematic side view of a PV device according to another embodiment of the present invention;

FIG. 4—illustrates a schematic view of a PV device according to still another embodiment of the present invention;

FIG. 5—presents an energy diagram of a PV device according to the embodiment of the invention illustrated in FIG. 3; and

FIG. 6—is a flow chart illustrating a method for preparing a photovoltaic device according to an embodiment of the present invention.

### DETAILED DESCRIPTION

According to one embodiment of the present invention, a photovoltaic device is provided, having a graphene as the active material for harvesting solar energy. In the following example, the graphene is a mono-layer or in multi-layers being in essentially a pristine form. The graphene may be mounted as a transistor, between two electrodes which are made from different materials, while the substrate of the device can be any material including different oxides (e.g. a glass), different plastic materials or silicon wafers, where the silicon can be used also for electrical gating of the graphene. In general any substrate which the electrodes can be printed on and the graphene sheets can be laid on, is a suitable candidate to be used as a substrate. Under the substrate there may be a reflecting material to reflect the access photon flux back to the grapheme layer(s). In many photovoltaic (PV) devices, the moving direction of the electrons and holes is determined by the electric field induced by the two electrodes. The field thus created, conveys the electrons to the negative side (the n-type electrode) and the holes to the positive side (the p-type electrode). When an external current is provided, electrons will flow to the positive side to unite with holes that the electric field conveyed thereto. The electron flow creates the current, and the cell's electric field causes a voltage, and the overall effect is of the power that may be retrieved.

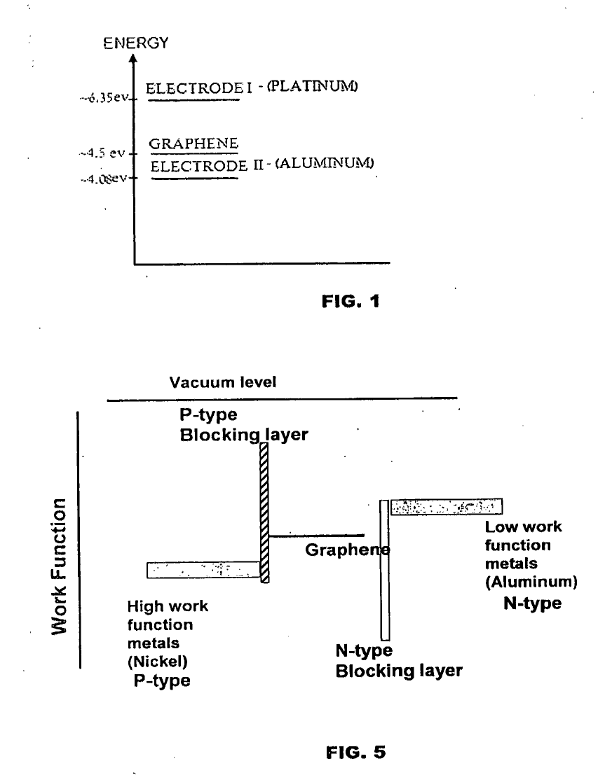

According to the present invention, the selection of electrodes is made to ensure that one electrode has a working function higher than the active material, whereas the second electrode has a work function lower than the active material. This way an electric field may be generated across the active material without the need to apply any external voltage onto the electrodes. FIG. 1 illustrates the energy level of the working function of two example electrodes and an active material according to the present invention. As may be seen from this Fig., the working function of the first electrode (in this example—Platinum) is higher than the graphene's (being the active material in this example) working function, while the working function of the second electrode (in this example-Aluminum) is lower than the graphene's working function. According to another embodiment of the present invention the metal electrodes work function affect the doping level of the active material next to the electrodes. The active material will become n-doped if the contact electrode injects electrons to the active material, and P doped if the contact electrode injects holes to the active material. In addition, by using a substrate that can be gated, the graphene doping level can be tuned at the center, or at other parts, and the electrodes can be interlocked to achieve large area of p-n Junction.

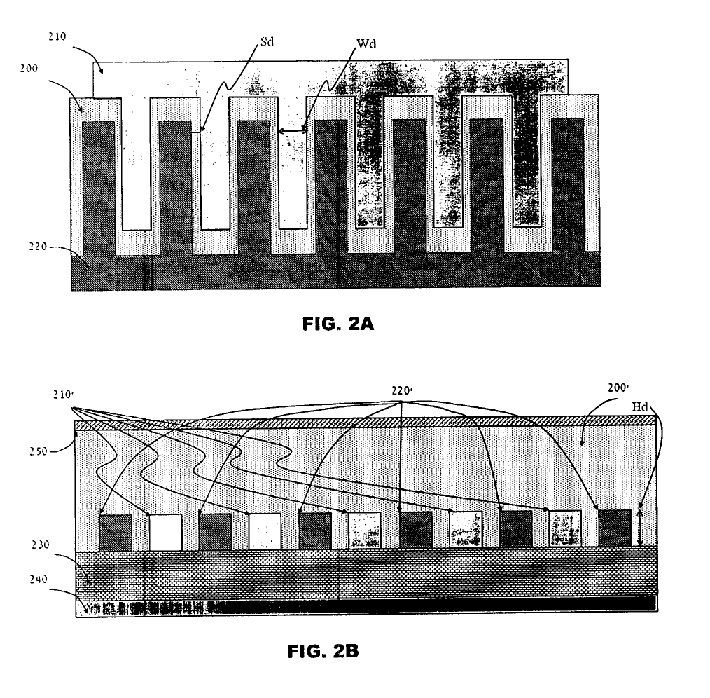

FIG. 2A is a top view of the PV device, and FIG. 2B is a side view of a PV device according to an embodiment of the invention, and when taken together, they may serve to provide a comprehensive understanding of the PV device dimensions. According to this example, the separation between the two electrodes (210 and 220) is between 1 to 10 micron (the separation distance is shown in FIG. 2A as Sd). Typically, the separation between the electrodes should be as small as possible, say less than 1 micron, e.g. 100 nm. In this example, graphene is the active material (200) which is located between the two electrodes. According to an example of this embodiment of the invention, the width of electrodes should also be as small as possible e.g. between 1 micron and 50 micron, and in some embodiments between down to about 10 nm. The width of the electrons is shown in FIG. 2A as Wd.

Turning now to FIG. 2B, where the side view of the PV device is illustrated, 200′ is the active material, 210′ and 220′ are the electrodes, 230 is the substrate, 240 is a reflecting layer, and 250 is an isolation layer placed on top of the active layer and the electrodes for their protection from oxidation and contamination. The height (thickness) of the electrodes may be very small, for example between 10 nm to 50 nm, and if technology enables an electrode height of a smaller dimension than 10 nm, it is also applicable according to the present invention. The height of the electrons is shown in FIG. 2B as Hd.

According to another embodiment, the material that can be used for both electrodes may be the same material on which the active material can be grown, e.g. by applying chemical vapor deposition (CVD) of graphene. Another option is to print the active material onto the desired substrate. In the case of graphene it can be printed on an isolating material such as glass or silicon dioxide (SiO2) and deposition of metal such as aluminum below the glass may be used as a reflector. The electrodes may be evaporated on the substrate as an inter-digitated electrodes (fork shaped) or on top of the graphene after mounting the latter on the substrate, thus covering a large active area.

The active material in accordance with this invention may be any material (or any combination of materials either in a way of compound or in a way of mixture e.g. layers of graphene and silicon) that enables to produce photo-current when being illuminated. The choice of the active material in the PV device according to the present invention is based (among other possible factors) on its work function.

The work function is a characteristic property for any solid matter. It is defined as the minimum energy required to remove an electron from a solid to a point being immediately outside the solid surface, and is typically measured in electron volts.

Graphene is typically manufactured in sheets only 1 atom thick and up to several layers, (e.g. 7). It can absorb light in a number of frequencies like in the visible band and the IR band which is not absorbable by silicon. The graphene when used as an active material for the PV device of the present invention may comprise one or more layers of graphene sheets. When the graphene is illuminated, electron-hole pairs are photo excited and react with the electrodes induced electric field. The charges will be collected respectively at the electrodes, i.e. electrons to one electrode and holes to the other.

There are many ways to grow and transfer the graphene. A non-limiting example is growing the graphene by CVD method on Co, Pt, Ru, Ni, Cu or any other transition metal as a substrate. Then the CVD grown graphene can be transferred by etching the metal substrate and generating free standing graphene or by etching the metal substrate after attaching a transfer material on top of the graphene, like PDMS. Still, it should be understood that other non-CVD growing methods of single sheet graphene may be applicable to carry out the present invention. Another example for growing the graphene may be to grow it on patterned electrodes shaped already as the device described above, as inter digitaded electrodes from two different substances e.g. metals. By another example, the graphene is grown on one type patterned metal and having the second electrode deposited on top to generate a device as described before, resulting in inter digitated electrodes made of two different substances e.g. metals.

The following example describes steps of an experiment for measuring the effectiveness of the PV device according to the present invention.

i. Preparing substrate with an electrodes according to the present invention;

ii. Preparing and growing CVD graphene sample, according to any method known in the art per se;

iii. Printing the graphene onto the substrate that constitutes the base for the electrodes; and

iv. Measuring photo current and dark current as a function of bias, wavelength and power (incident).

According to another embodiment of the present invention, the electrodes of the PV device may comprise a buffering material/layer substantially covering the metal core of the electrode. The buffering layer may be used to block one type of charge carriers (i.e. electrons or holes). The buffering layer thickness can be between 10 nanometers up to 100 nanometers, but also may well be less than 10 nanometers. The buffering layer defined as substance which separates between the active material and the core of the electrode, and that its transport properties match the type of carriers that need to be conveyed to the electrode. Each electrode's blocking layer may be characterized by having a different working function, this enables to use the same metal for both electrodes' cores in the PV device, and still be able to have an electric field generated between the electrodes and across the device as explained hereinbefore.

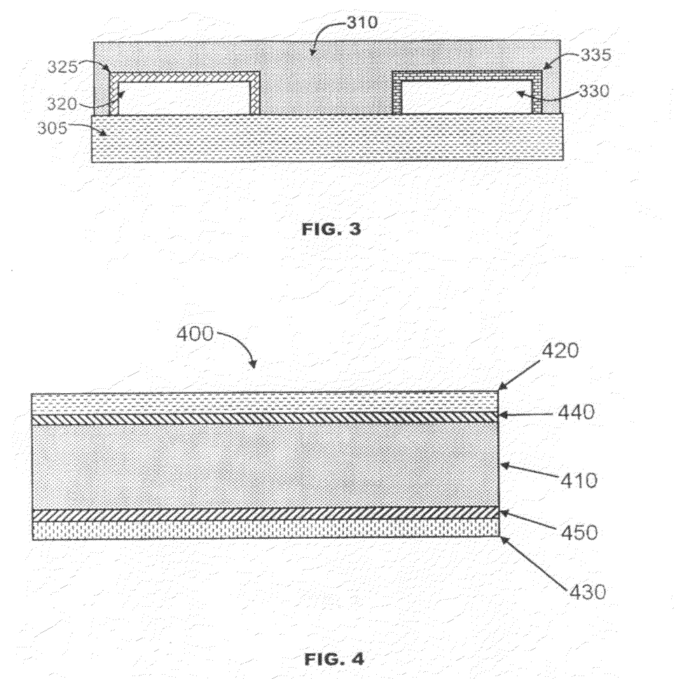

A demonstration to this embodiment is presented in FIG. 3. In the PV device demonstrated in this non-limiting example, glass is used as a substrate (305), graphene for the active layer (310), while platinum (Pt) as the core of the first electrode (320) and aluminum (Al) as the core of the second electrode (330). The buffering layer of the first electrode (325) allows charge carriers of the holes type to be conveyed along to the electrode, while blocking charge carriers of the electrons type which should be conveyed to electrode (320). The buffering layer located of the second electrode (335) enables conveying of charge carriers of the electron type therethrough, while blocking charge carriers of the holes type from being conveyed to the second electrode (330). In other words, the blocking material is selected so that it allow the transport of one member of the group consisting of charge carriers of the holes type and charge carriers of the electrons type, while blocking the other member of that group. Since the first electrode is a P-type electrode with reference to the graphene, the buffering layer of the first electrode (325) may be a P-type oxide e.g. NiO, MoO₃ (molybdenum trioxide), V₂O₅ (vanadium pentoxide), and the like. In general, the buffering layer (325) may be any transition metal oxide having sufficient holes conductivity. Accordingly, since the second electrode is an n-type electrode with reference to graphene, the buffering layer of the second electrode (335) may be an n-type oxide or an ionic salt such as LiF (Lithium Fluoride), CaF2 (Calcium Fluoride), LiCl (Lithium Chlorine), and the like. Generally, any combination of an alkali metal of the first column of the periodic table with a seventh column's elements (halogens), or alkali earth element of the second column of the periodic table with halogens, may serve as an n-type buffering layer.

As will be appreciated by those skilled in the art, the above example where two different metals were used for the electrodes' cores are specific examples and should not be considered as limiting of the present invention. Other cases may be when the core material from which the two electrodes are made of, is the same material, and only the coating type of the two electrodes is different. Consequently, each electrode will end having a different working function than the other.

FIG. 4 illustrates a different type of a PV device construed according to an embodiment of the present invention. This device 400, is a ‘sandwich type cell’, in which graphene layers 410 are stacked in between the anode 420 and the cathode 430, which are covered with an hole blocking layer 440 and an electron blocking layer 450, respectively. The electric driving force in this configuration is parallel to the stacking direction. Preferably, in such a configuration the graphene layers may vary from a single graphene layer up to tens of layers, stacked on top of each other. In order for this device to be transparent (as light needs to penetrate the electrode and its respective blocking layer), the top electrode may be made out of ITO (indium tin oxide) or any other transparent conductor.

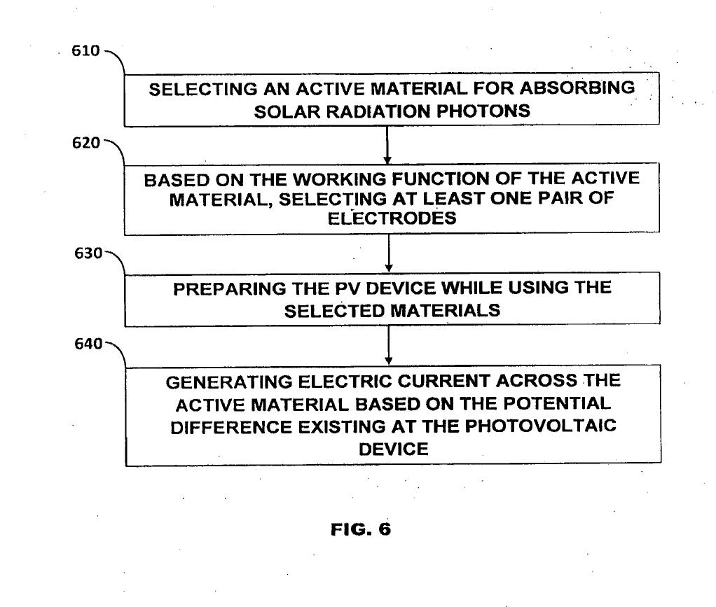

FIG. 5 shows an energy diagram of the PV device presented in FIG. 3, (with reference to the vacuum level).

FIG. 6 illustrates a method for preparing a PV device (e.g. a solar cell) according to an embodiment of the present invention. First (step 610) an active material is selected for absorbing=the photons reaching the PV device from incident solar radiation. This active material is associated with a pre-defined working function. Next, based on the working function of the active material, at least one pair of electrodes is selected (step 620) for use in the PV device. This selection is made while ensuring that one member of the at least one pair of electrodes has a lower working function than that of the active material, whereas the other member of that pair has a higher working function than that of the active material. Once the design of the various components of the PV device is completed, the PV device is prepared by using the selected materials (step 630). This step may be carried out according to any method known in the art per se. One example of carrying out the method is the following: (i) preparing substrate using the selected electrodes; (ii) preparing and growing CVD graphene active material; and (iii) printing the graphene onto the substrate. Next, (step 640) generating electric current across the active material based on the potential difference existing between the two members of the at least one pair of electrodes.

As will be appreciated by those skilled in the art, the examples provided show the design of various photovoltaic devices. However, similar processes may be applied in a similar way in order to accommodate different devices, without departing from the scope of the present invention. For example, although it has been described hereinbefore that the selection of the active material and the two electrodes is made by selecting first the active material and then the material of the two electrodes while ensuring that the working function of one electrode is higher than that of the active material while that of the other electrode is lower therefrom, it should be understood that a similar selection process may be carried out, by selecting first the material of one of the electrodes, and then the remaining constituents of the device as long as the above condition of the working function is satisfied.

It is to be understood that the above description only includes some embodiments of the invention and serves for its illustration. Numerous other ways of carrying out the methods provided by the present invention may be devised by a person skilled in the art without departing from the scope of the invention, and are thus encompassed by the present invention.

1. A photovoltaic device, comprising:
at least one pair of electrodes wherein each member of the at least one pair of electrodes having a different working function than the other; and
one or more layers made of graphene located between the at least one pair of electrodes, wherein the one or more layers made of graphene have a lower working function than a working function of one member of the at least one pair of electrodes, and a higher working function than a working function of the other member of the at least one pair of electrodes.

2. A photovoltaic device according to claim 1, wherein both electrodes of the at least one pair of electrodes are made of the same core material, but each of said electrodes has a coating of a different buffering material than the other.

3. A photovoltaic device which comprises a silicon-based photovoltaic device located in parallel and adjacent to the graphene based photovoltaic device of claim 1.

4. A photovoltaic device according to claim 1, wherein a gap smaller than about 15 microns separates between the at least one pair of electrodes.

5. A photovoltaic device according to claim 1, wherein the one or more layers made of graphene are grown on the same material as the material used for at least of one of the electrodes belonging to the at least one pair of electrodes.

6. A photovoltaic device according to claim 1, wherein at least one member of the at least one pair of electrodes, is associated with a buffering layer.

7. A photovoltaic device according to claim 1, wherein at least one member of the at least one pair of electrodes, is further comprising a buffering layer adapted to block one type of charge carriers selected from among electron type and holes' type.

8. A photovoltaic device according to claim 1, wherein at least one n-type electrode comprises a material comprising an alkali-metal or an alkali-earth element being in combination with a halogen.

9. A photovoltaic device according to claim 1, wherein at least one p-type electrode comprises a material comprising a transition metal oxide and characterized by having a substantially high holes' conductivity.

10. A module for use in collecting solar radiation which comprises a plurality of photovoltaic devices of claim 1.

11. A solar panel for use in collecting solar radiation which comprises a plurality of photovoltaic devices of claim 1.

12. A method for generating electric power by using a photovoltaic device, comprising:
providing one or more layers made of graphene to be placed between at least one pair of electrodes, wherein the one or more layers made of graphene have a defined working function;
based on the working function of the one or more layers made of graphene, determining a material for the at least one pair of electrodes, wherein one member of the at least one pair of electrodes has a lower working function than that of the one or more layers made of graphene, and the other member of that pair has a higher working function than that of the one or more layers made of graphene;
preparing a PV device that contains the one or more layers made of graphene provided and the selected at least one pair of electrodes; and
generating an electric field across the one or more layers made of graphene based on the potential difference existing between the two members of the at least one pair of electrodes.

13. A method according to claim 12, wherein at least one member of the at least one pair of electrodes, is associated with a buffering layer, for blocking charge carriers that should be conveyed towards the other member of that at least one pair of electrodes.

14. A method according to claim 12, wherein at least one n-type electrode comprises an alkali-metal or alkali-earth element being in combination with a halogen.

15. A method according to claim 12, wherein at least one p-type electrode is comprises a transition metal oxide and characterized by having a substantially high holes' conductivity.

16. A photovoltaic device according to claim 1, comprising at least one n-type electrode and at least one p-type electrode and configured to allow an electric current to pass in one direction while blocking current in the opposite direction.
